(19) United States
(12) Patent Application Publication
(10) Pub. No.: US 2005/0253646 A1
(43) Pub. Date: Nov. 17, 2005

(54) Global Automatic RC Time Constant Tuning Circuit and Method for on Chip RC Filters

(76) Inventor: Joanna Lin, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 10/906,869

(22) Filed: Mar. 10, 2005

(30) Foreign Application Priority Data
May 14, 2004 (TW) 093113711

(51) Int. Cl. H03B 1/00

(52) U.S. Cl. 327/553

(57) ABSTRACT

A method for RC time constant tuning includes biasing a reference resistor and charging a reference capacitor, transmitting a start signal to a counter when beginning charging, inputting the results of biasing and charging to a comparator for comparing, and sending a stop signal to the counter when the result of the comparison conforms to a predetermined rule, counting a number of clock cycles received by the counter from the time of receiving the start signal to the time of receiving the stop signal, and deciding a number of resistors or a number of capacitors utilized by an RC filter according to the number of the clock cycles received by the counter.

### BACKGROUND OF INVENTION

1. Field of the Invention

The present invention relates to an RC time constant tuning circuit and a related method, and more particularly, to an RC time constant tuning circuit and a related method that decides a number of resistors or a number of capacitors utilized by an RC filter according to the number of the clock cycles received by the counter.

2. Description of the Prior Art

Filters are utilized commonly in many fields of communication. As is widely known, the variance of resistor-capacitor filters (RC filters) is smaller than that of gmC filters. Hence RC filters are more controllable and broadly adopted, however, there are still variances in RC filter designs. Therefore, the actual value of the RC time constant is not always identical to the design value of the RC time constant, and the accuracy of the filter and the performance of filtering are consequently affected. Without calibration, the difference between the actual value and the design value of the RC time constant may be as high as ±30%˜50% (depending on the adopted resistors and capacitors). In consequence, the performance of the RC filter shifts over a dramatic range, which is very unfavorable to circuits that need a precise frequency response.

For adjusting the error of RC time constants resulting from fabrication variation, there are numerous tuning circuits and related methods. One popular method is to utilize external high-precision resistors and capacitors for compensating the aforementioned error resulting from fabrication variation. However, the benefits of advances in the integration of filters into ICs (integrated chips), such as small volume, low cost and concise distributing lines are decreased, since external resistors and capacitors are utilized in this method of compensation.

In light of the known drawbacks of the method for RC time constant compensation utilizing external resistors and capacitors, another circuit is put forward in the prior art for providing a tunable RC time constant to the filter by utilizing active resistors. Active resistors are made of metal-oxide-semiconductor field effect transistors (MOSFETs), and the resistance value is adjusted by controlling the MOSFETs. In this conventional circuit for adjusting RC time constant, a feedback circuit for measuring the actual value of the RC time constant is utilized. The feedback circuit provides a feedback signal to the MOSFETs, that is, the active resistors, and adjusts the resistance value continuously to achieve the design value of the RC time constant. Though this tuning circuit does not utilize external resistors and capacitors, power consumption is increased due to the utilization of active resistors. Also, the MOSFETs make such designs more difficult to implement in a low voltage potential environment.

The most popular tunable filter adopts a resistor-capacitor network (RC network) comprising passive resistors and a tunable array of capacitors. This conventional method modifies the RC time constant of the filter by adjusting the number of capacitors connected to the RC network of the filter. Compared to previous tuning circuits that utilize active resistors, the frequency performance of tunable filters that adopt RC networks is more linear, and power consumption is lower since passive elements are utilized instead of active ones. Usually, this conventional circuit utilizes a reference RC network comprising duplicates of the resistors and the array of capacitors adopted by the filter. Please refer to FIG. 1. FIG. 1 is a flowchart of the prior art method for RC time constant tuning. First of all, an RC time constant of the reference RC network is measured in step 110. If the RC time constant of the reference RC network measured in step 110 is different from the expected RC time constant (design value), the number of the capacitors connected to the reference RC network is adjusted in step 130, and then the RC time constant of the reference RC network is measured again in step 110. The loop of step 110, step 120 and step 130 will be repeated until the difference between the measured RC time constant and the expected RC time constant (design value) is less than a predetermined value. When the difference between the measured RC time constant and the expected RC time constant is less than a predetermined value, the numbers of the resistors and capacitors adopted by the RC filter is determined according to the number of the capacitors connected to the reference RC network in step 140. Since the resistors and capacitors connected to the reference RC network are duplicates of the resistors and capacitors utilized by the RC filter, the process variation should be identical theoretically. Therefore, the number of the capacitors connected to the RC filter may be determined according to the number of capacitors connected to the reference RC network. Hence the shift of the RC time constant due to process error can be compensated for, and the frequency response of the RC filter is calibrated accordingly.

As illustrated in FIG. 1, in the prior art, a reference RC network adopting duplicates of the resistors and capacitors adopted by the filter is utilized. By adjusting the number of capacitors connected to the reference RC network, the design value of the RC time constant of the reference RC network may be obtained. Step 110 is repeated for measuring the RC time constant of the reference RC network whenever the number of capacitors connected to the reference RC network is adjusted. It is very wasteful in terms of time to repeat the loop of step 110, step 120 and step 130. Furthermore, the resistors and the array of capacitors of the RC filter that need to be duplicated in order to form the reference RC network, occupy a huge area of IC.

For decreasing the time required to carry out the abovementioned adjustment(s), there are many algorithms for adjusting the number of capacitors connected to the reference RC network, e.g. linear search and even binary search. However, no matter what algorithm is utilized, it still takes a relatively long time to identify the most appropriate number of capacitors to be connected to the reference RC network for making the actual RC time constant equal to the design value. Naturally, this problem will be compounded if the circuit comprises more than one filter. And, as mentioned above, the total area of the IC will inevitably be increased by the resistor and capacitor arrays that need to be duplicated in order to form the reference RC network of each filter.

### SUMMARY OF INVENTION

This invention provides an RC time constant tuning circuit and related methods.

Briefly described, the claimed invention discloses a semiconductor device with a resistor-capacitor filter (RC filter). The device includes an RC filter and a tuning circuit capable of tuning an RC time constant of the RC filter. The RC filter includes a resistor network and a capacitor network. The tuning circuit includes: a reference resistor and a reference capacitor (the materials of which are the same as the materials of the resistors and the capacitors of which the resistor network and the capacitor network comprise respectively), a first current source and a second current source electrically connected to the reference resistor and the reference capacitor respectively, a comparator capable of outputting a stop signal when two input signals conform to a predetermined relationship, a counter capable of receiving a start signal, a clock sequence and the stop signal, counting the number of clock cycles of the clock sequence that are received between the time of receiving the start signal and the time of receiving the stop signal, and generating a counting signal according to the number of clock cycles of the clock sequence, and a decoder capable of generating a tuning signal when receiving the counting signal and transmitting the tuning signal to the RC filter for setting the number of resistors and the number of capacitors adopted by the RC filter.

The claimed invention further discloses a method for RC time constant tuning. The method includes biasing a reference resistor and charging a reference capacitor, transmitting a start signal to a counter when beginning charging, inputting the results of biasing and charging to a comparator for comparing, and sending a stop signal to the counter when the result of the comparison conforms to a predetermined rule, counting a number of clock cycles received by the counter from the time of receiving the start signal to the time of receiving the stop signal, and deciding a number of resistors or a number of capacitors to be utilized by an RC filter according to the number of clock cycles received by the counter.

It is an advantage of the claimed invention that only one time of measurement of the RC time constant of the tuning circuit is needed for tuning the RC time constant of the RC filter. In the claimed invention, there is no need to duplicate the resistors and capacitors of the filter. Hence the area of IC is reduced as well.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a flowchart of the prior art method for RC time constant tuning.

FIG. 2 is a block diagram of the present invention semiconductor device.

FIG. 3 is a flowchart of the present invention method for RC time constant tuning.

FIG. 4 is a block diagram of the present invention semiconductor device with a plurality of RC filters.

FIG. 5 is a flowchart of the present invention method for globally tuning RC time constants.

### DETAILED DESCRIPTION

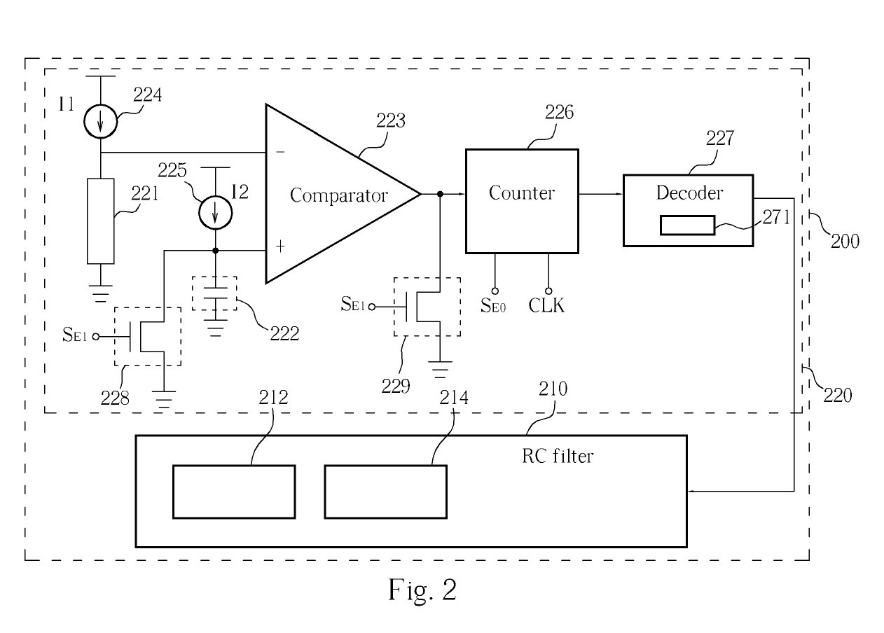

Please refer to FIG. 2. FIG. 2 is a block diagram of the present invention semiconductor device 200. The semiconductor device 200 comprises an RC filter 210 and a tuning circuit 220. The RC filter 210 includes a resistor network 212 comprising a plurality of resistors and a capacitor network 214 comprising a plurality of capacitors. The tuning circuit 220 is responsible for controlling the numbers of adopted resistors and adopted capacitors for tuning the RC time constant of the RC filter 210. The tuning circuit 220 includes a reference resistor 221, a reference capacitor 222, a first current source 224, a second current source 225, a comparator 223, a counter 226 and a decoder 227. The material of the reference resistor 221 is the same as the material of the resistors of the resistor network 212, and the material of the reference capacitor 222 is the same as the material of the capacitors of the capacitor network 214. The current provided by the first current source 224 is 11, and the current provided by the second current source 225 is 12. In the claimed invention, 12 may be designed to be a predetermined multiple of 11, in which case it can be assumed that 12=k·11. The first current source 224 connects to both the reference resistor 221 and the first input end of the comparator 223, and the second current source 225 connects to both the reference capacitor 222 and the second input end of the comparator 223. When the input signals of the first input end and the second input end of the comparator 223 conform to a predetermined relationship, the comparator 223 generates a stop signal and outputs it to the counter 226. The counter 226 is capable of counting the number of clock cycles of the clock sequence that are received between the time when the second current source 225 starts to charge the reference capacitor 222 and the time of receiving the stop signal output from the comparator 223, generating a counting signal according to the number of received clock cycles, and outputting the counting signal to the decoder 227. The decoder 227 outputs a tuning signal according to the counting signal and the information stored in an inner mapping unit 271 to the RC filter 210 for determining the number of resistors adopted by the resistor network 212 and the number of capacitors adopted by the capacitor network 214. This way, a correct RC time constant of the RC filter 210 may be obtained. Moreover, for convenience of control, two enabling units 228 and 229 may be added to the tuning circuit 220.

In the claimed tuning circuit 220, the complexity of the counter 226 depends on the expected tuning accuracy and the required tuning range. For example, assume the expected tuning accuracy of the tuning circuit 220 of the claimed semiconductor device 200 is to within 1% of a design value, and the required tuning range is ±50%. That is, the counter 226 has to be capable of counting 100+50=1 50 clock cycles in total. Therefore, in this example, the tuning circuit 220 needs to adopt an 8-bit counter. Furthermore, one advantage of the present invention is that there is no need to duplicate the whole resistor network and the whole capacitor network for the tuning task. For the description given below it's necessary to assume that: the design resistance value of the resistor network 212 connected by the claimed RC filter 210 is R, the design capacitance value of the capacitor network 214 connected by the claimed RC filter 210 is C, the resistance value of the reference resistor 221 is designed as 1/x of R, and the capacitance value of the reference capacitor 222 may be designed as 1/y of C. That is, the number of resistors comprised in the reference resistor 221 is 1/x of the number of resistors connected to the RC filter 210, and the number of capacitors comprised in the reference capacitor 221 is 1/y of the number of capacitors connected to the RC filter 210. Therefore, the resistance value of the reference resistor 221 is R/x, and the capacitance value of the reference capacitor 222 is C/y. Only parts, not the whole of the resistor and capacitor networks of the RC filter 210 need to be duplicated to form the reference resistor 221 and the reference capacitor 222. Hence the volume of the total circuit may be reduced.

Assume the period of the clock cycles of the clock sequence adopted by the claimed semiconductor device 200 is Tc. When the semiconductor device 200 sends out an enabling signal S_{E0}(S_{E1} is a reverse signal of S_{E0}), the present tuning circuit 220 starts to tune the RC time constant. At the time when the enabling signal S_{E0} is sent out, the counter 226 starts to count the number of received clock cycles. The enabling units 228 and 229 receive the reverse enabling signal S_{E1} at the same time, which makes the second current source 225 start to charge the reference capacitor 222, and initiates the voltage potential of the input end of the counter 226. When the potentials of the reference capacitor 222 and the reference resistor 221 conform to a predetermined relationship, e.g. equivalence or within a predetermined range, the state of the output signal of the comparator 223 changes, e.g. from low state to high state. The state change of the output of the comparator 223 serves as a stop signal to the counter 226. An equation is obtained as illustrated below:
I·R/x=k·I·y/C·100 Tc (1)
which may be simplified to:
   R·C=x·y·k·100 Tc (2)

It is clearly shown that the current I is cancelled in equation (2). That is, the accuracy of the current sources does not affect the tuning accuracy of the present invention since the current provided by the second current source 225 is designed to be a predetermined multiple of the current provided by the first current source 224. Further, R. C is a time constant of the filter decided by a predetermined frequency response, 100 is a fixed accuracy, and Tc is the clock cycle period. When the three aforementioned items are all fixed, x, y and k remain as the three tuning circuit variables. Therefore, the equation (2) is always solvable.

As the second current source 225 charges the reference capacitor 222 (of capacitance value C/y), the state of the output of the comparator 223 changes from low to high when the potential of the capacitor 222 rises to a predetermined level. The change of the output state acts as a stop signal to the counter 226, which makes the counter 226 stop counting the number of received clock cycles. The stop signal may also be utilized to notify the system that the task of tuning is complete. The power to the tuning circuit 220 may be shut down when the tuning task is complete in order to save power.

Assuming there is no variation in the fabrication of the semiconductor device 200, then according to the original design the output state of the comparator 223 should change when the counter 226 receives 100 clock cycles, that is, when the reference capacitor 222 has been charged by the second current source 225 for 100 Tc. If, however, there is fabrication variation and that variation causes the value of R·C to decrease, the counter 226 will receive the stop signal from the comparator 223 before the 100th clock cycle is received. For instance, if the R·C value decreases by 15% due to fabrication variation, the counter 226 will only receive 85 clock cycles before receiving the stop signal from the comparator 223. Similarly, if the R·C value increases by 40% due to fabrication variation, the counter 226 will receive 140 clock cycles before receiving the stop signal from the comparator 223. In other words, the shift of the R·C value can be reflected by the number of received clock cycles counted by the counter 226. Since the material of the reference resistor 221 of the tuning circuit 220 is identical to the material of the resistors of the resistor network 212, and the material of the reference capacitor 222 is identical to the material of the capacitors of the capacitor network 214, the shift of the RC time constant of the tuning circuit 220 is equal to the shift of the RC time constant of the RC filter 210. Therefore, the present tuning circuit 220 is capable of determining the numbers of adopted resistors and capacitors of the RC filter 210 by only one charging cycle and one comparison. Taking the aforementioned embodiment by way of example, and assuming the resistor network 212 adopted by the present filter 210 is fixed and the capacitor network 214 is a tunable capacitor array, then when the counter 226 counts only 85 clock cycles while 100 clock cycles are expected, the decoder 227 sends out a tuning signal for determining the number of adopted capacitors in the capacitor network 214 of the RC filter 210 incorporating a factor of 100/85 times the design value according to the information of the mapping unit 271.

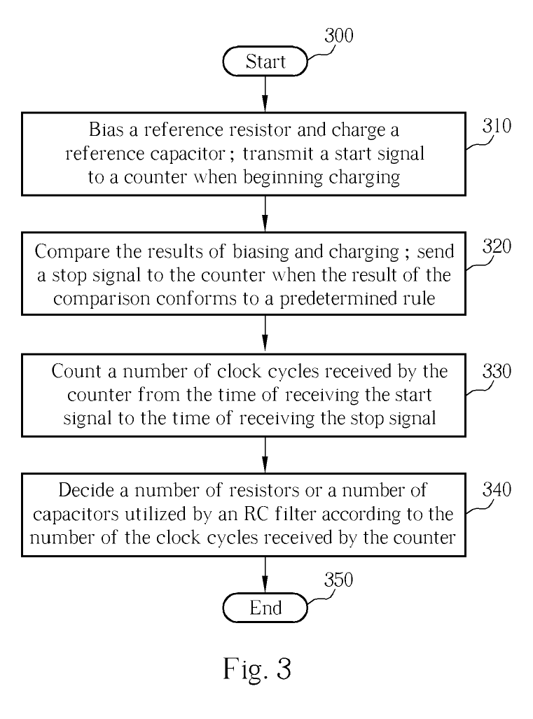

Please refer to FIG. 3. FIG. 3 is a flowchart of the present invention method for RC time constant tuning.
Step 300: Start;
Step 310: Bias a reference resistor and charge a reference capacitor; transmit a start signal to a counter when the charging begins;
Step 320: Compare the results of charging and biasing; send a stop signal to the counter when the result of the comparison conforms to a predetermined rule;
Step 330: Count a number of clock cycles received by the counter from the time of receiving the start signal to the time of receiving the stop signal;
Step 340: Decide a number of resistors of the resistor network or a number of capacitors of the capacitor network utilized by an RC filter according to the number of received clock cycles;
Step 350: End.

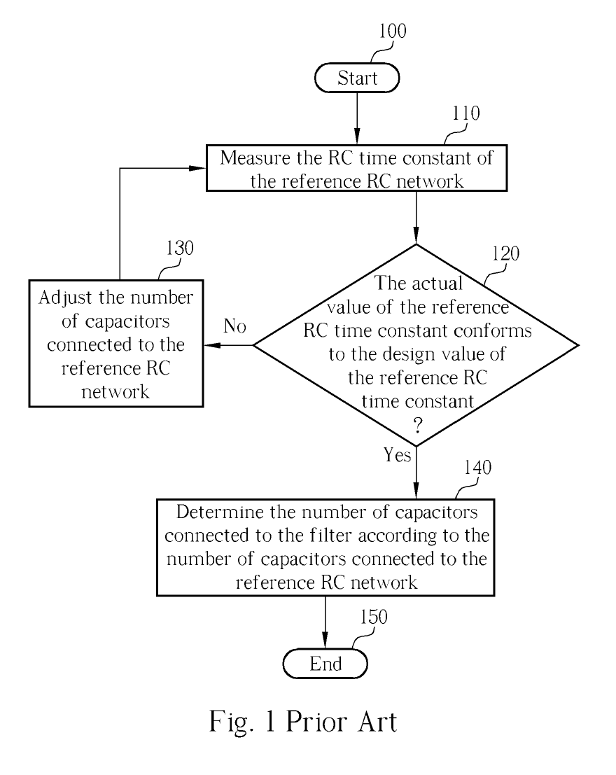

As illustrated in FIG. 3, in the present method for tuning the RC time constant, it is not necessary to adjust the capacitance value and measure the RC time constant iteratively, as it is in the prior art as shown in FIG. 1. Only a single measurement of the RC time constant is enough. The number of adopted resistors in the resistor network and the number of adopted capacitors in the capacitor network can be determined according to the measured RC time constant. For example, in the aforementioned embodiment, the RC filter 210 adopts a fixed resistor network and a tunable capacitor network. According to the present method for tuning the RC time constant, the number of capacitors connected to the capacitor network can be determined when the RC time constant is measured by the claimed RC time constant tuning circuit.

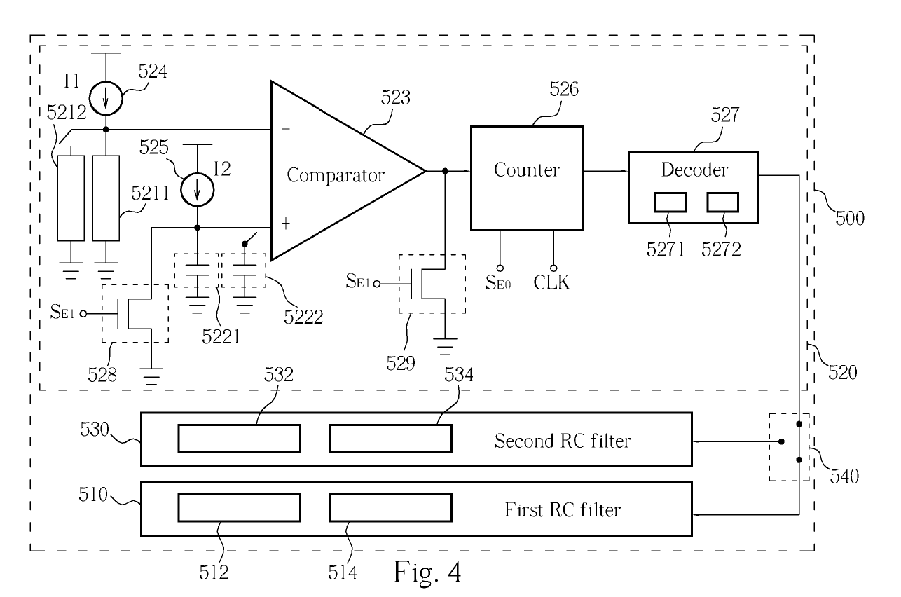

The present invention may be applied to semiconductor devices comprising a plurality of RC filters having different resistor networks and capacitor networks. Please refer to FIG. 4. FIG. 4 is a block diagram of the present invention semiconductor device 500. The semiconductor device 500 includes a first RC filter 510 and a second RC filter 530, and the materials of resistor network and capacitor networks adopted by the two filters are different. Therefore, the tuning tasks of the two filters have to be performed separately. The first RC filter 510 comprises a first resistor network 512 and a first capacitor network 514. The second RC filter 530 comprises a second resistor network 532 and a second capacitor network 534. The global tuning circuit 520 is capable of tuning the RC time constants of the two RC filters of the semiconductor device 500. 5211 is a first reference resistor which, either comprises material which is the same as the material of the resistors of the first resistor network 512, or is a duplicate of a part of the first resistor network 512 directly. 5212 is a second reference resistor which, either comprises material which is the same as the material of the resistors of the second resistor network 532, or is a duplicate of a part of the second resistor network 532 directly. 5221 is a first reference capacitor which, either comprises material of which is the same as the material of the capacitors of the first capacitor network 514, or is a duplicate of a part of the first capacitor network 514 directly. And 5222 is a second reference capacitor which, either comprises material of which is the same as the material of the capacitors of the second capacitor network 534, or is a part of the second capacitor network 534 directly. The decoder 527 comprises mapping units corresponding to each RC filter, including a first mapping unit 5271 corresponding to the first RC filter 510, a second mapping unit 5272 corresponding to the second RC filter 530. The aforementioned description refers to the differences between block diagrams illustrated in FIG. 4 and FIG. 2. Regarding the comparator 523, the first current source 524, the second current source 525, the counter 526, and the two enabling units 528 and 529, their functions are the same as the corresponding devices illustrated in FIG. 2, hence descriptions are not repeated.

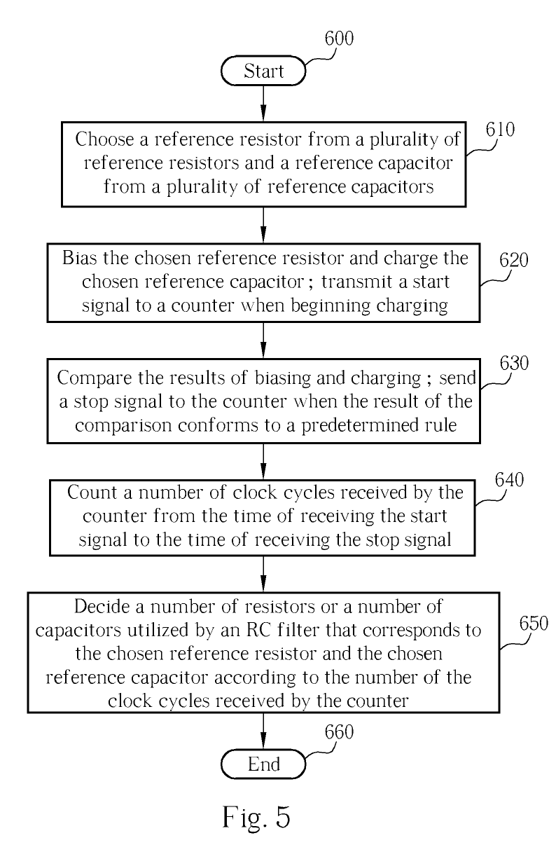

FIG. 5 is a flowchart of the present invention method for globally tuning RC time constants. The operations of devices illustrated in FIG. 4 are now demonstrated with the flowchart illustrated in FIG. 5. When the present global tuning circuit 520 is utilized to perform global tuning of a semiconductor device comprising a plurality of RC filters, e.g. when a system is started up or a PC is turned on, the global tuning circuit 520 chooses a resistor network and a capacitor network to be connected according to the RC filter, the RC time constant of which is assigned to be tuned at the time (step 610). For instance, when the claimed global tuning circuit 520 is required to perform tuning task on the first RC filter 510, the global tuning circuit 520 connects the first current source 524 to an input end of the comparator 523 and the first reference resistor 5211, which corresponds to the first RC filter 510 for biasing the first reference resistor 5211, and connects the second current source 525 to another input end of the comparator 523 and the first reference capacitor 5221 which corresponds to the first RC filter 510 for charging the first reference capacitor 5221. At the same time as biasing and charging begin, a start signal is transmitted initiating the counter 526 and commanding the counter 526 to count the number of received clock cycles (step 620). When the result of charging and biasing conform to a predetermined rule, the comparator 523 will output a stop signal to make the counter 526 stop to count the number of received clock cycles (step 630). The counter 526 starts to count the number of received clock cycles when the second current source 525 begins to charge the first reference capacitor 5221 and stops counting when the comparator 523 outputs a stop signal. Subsequently, the counter 526 outputs a counting signal to the decoder 527 according to the result of the count (step 640). The decoder 527 determines the number of resistors of the resistor network or the number of capacitors of the capacitor network adopted by the RC filter, and hence the RC time constant which is tuned (step 650). Similarly, if it is the second RC filter 530 that is tuned, the switch controller 540 will switch off. The second reference resistor 5212 that corresponds to the second RC filter 530 is then connected to the first current source 524, and the second reference capacitor 5222 is then connected to the second current source 525 as well. By performing the aforementioned steps 610 to 650, the task of tuning the RC time constant of the second RC filter 530 can be achieved as well.

In the present invention, it is easy to broaden the circuit for RC time constant tuning into a global tuning circuit for tuning the RC time constants of all RC filters of the system. Only parts of the resistor network and the capacitor network of different RC filters need to be duplicated in the tuning circuit. And, mapping units with corresponding information are located in the decoder. In this way, the RC time constants of all RC filters in the system may be tuned up separately.

In summary, the claimed invention introduces a concise and small-area circuit and the related method for RC time constant tuning. In the present invention, there is no need to measure the RC time constant iteratively, only a single measurement of the RC time constant is enough. Therefore, initiation time is reduced substantially. Even though for systems comprising a plurality of RC filters that utilize resistor networks and capacitor networks of different materials, only parts of each resistor network and each capacitor network have to be duplicated in the tuning circuit. Other devices, such as the comparator and the counter, do not have to be duplicated in the tuning circuit. Compared to the prior art, the area of the present tuning circuit is small. Hence the cost of the present tuning circuit chip is reduced. Moreover, the claimed method for tuning RC time constants is not affected by the speed of clocks provided by the system. Additionally, the accuracy of the current source has no effect on the performance of the present tuning circuit.

Those skilled in the art will readily observe that numerous modifications and alterations of the device and method may be made while retaining the teachings of the invention. Accordingly, the above disclosure should be construed as limited only by the metes and bounds of the appended claims.

1. A semiconductor device comprising:
a first RC filter comprising a first resistor network and a first capacitor network; and
a tuning circuit capable of tuning an RC time constant of the RC filter.

2. The semiconductor device of claim 1, wherein the tuning circuit comprises:
a comparator capable of receiving signals from a first input end and a second input end and outputting a stop signal;
a counter capable of receiving a start signal, a clock sequence and the stop signal, counting a number of clock cycles of the clock sequence, and generating a counting signal according to the number of clock cycles of the clock sequence; and
a decoder capable of generating a tuning signal when receiving the counting signal and transmitting the tuning signal to the RC filter.

3. The semiconductor device of claim 2, wherein the comparator outputs the stop signal when the first input and the second input conform to a predetermined relationship.

4. The semiconductor device of claim 2, wherein the number of clock cycles of the clock sequence are received between the time of receiving the start signal and the time of receiving the stop signal.

5. The semiconductor device of claim 2, wherein the decoder comprises a first mapping unit, and the decoder generates the tuning signal according to the comparison between the counting signal and the data stored in the first mapping unit.

6. The semiconductor device of claim 2, wherein the tuning circuit further comprises a first current source and a reference resistor, both electrically connected to the end of the first input.

7. The semiconductor device of claim 2, wherein the tuning circuit further comprises a second current source, a reference capacitor and a first enabling unit all electrically connected to the end of the second input, the first enabling unit capable of controlling the second current source for initiating charging of the reference capacitor.

8. The semiconductor device of claim 7, wherein while the first enabling unit controls the second current source to charge the reference capacitor, the counter receives the start signal and begins counting the number of clock cycles of the clock sequence that are received.

9. The semiconductor device of claim 5, further comprising a second RC filter comprising a second resistor network and a second capacitor network.

10. The semiconductor device of claim 9, wherein the decoder further comprises a second mapping unit corresponding to the second RC filter.

11. The semiconductor device of claim 1, further comprising a second RC filter comprising a second resistor network and a second capacitor network.

12. The semiconductor device of claim 3, wherein the predetermined relationship is the voltage at the second input end exceeding the voltage at the first input end.

13. The semiconductor device of claim 7 wherein the current provided by the second current source is a predetermined multiple of the current provided by the first current source.

14. A method for RC time constant tuning comprising:
biasing a reference resistor and charging a reference capacitor, and transmitting a start signal to a counter when beginning charging;
inputting the results of biasing and charging of the biasing step to a comparator for comparing, and sending a stop signal to the counter when the result of the comparison conforms to a predetermined rule;
counting a number of clock cycles received by the counter from the time of receiving the start signal to the time of receiving the stop signal; and
deciding a number of resistors or a number of capacitors utilized by an RC filter according to the number of the clock cycles received by the counter.

15. The method of claim 14 wherein in biasing step, the reference resistor for biasing is chosen from a plurality of reference resistors and the reference capacitor for charging is chosen from a plurality of reference capacitors, and in deciding step, the RC filter corresponds to the reference resistor and the reference capacitor chosen in biasing step.

16. The method of claim 14 wherein in biasing step, two current sources are utilized to bias the reference resistor and charge the reference capacitor separately, wherein the current provided by one of the two current sources is a predetermined multiple of the current provided by the other current source.

17. The method of claim 14 wherein in inputting step, the predetermined rule is the voltage of the reference capacitor generated by charging exceeding the voltage of the reference resistor generated by biasing.
